(19) United States
(12) Patent Application Publication
(10) Pub. No.: US 2024/0260231 A1
(43) Pub. Date: Aug. 1, 2024

(54) FLOW PATH DIAGNOSIS METHOD, PROJECTOR, AND COOLING DEVICE

(71) Applicant: SEIKO EPSON CORPORATION, Tokyo (JP)

(72) Inventors: Kodai FURUKAWA, Matsumoto-shi (JP); Kazunori MAETA, Matsumoto-shi (JP); Shohei SHIMOMA, Matsumoto-shi (JP); Satoru NAGAREKAWA, Matsumoto-shi (JP)

(73) Assignee: SEIKO EPSON CORPORATION, Tokyo (JP)

(21) Appl. No.: 18/424,228

(22) Filed: Jan. 26, 2024

(30) Foreign Application Priority Data
Jan. 27, 2023 (JP) 2023-010790

(51) Int. Cl. H05K 7/20; G03B 21/16

(52) U.S. Cl. CPC H05K 7/20281; G03B 21/16; H05K 7/20272

(57) ABSTRACT

A flow path diagnosis method includes: acquiring the number of rotations of a pump configured to send a refrigerant for cooling a cooling target to a flow path through which the refrigerant circulates; acquiring an environmental temperature; setting a first threshold value as a threshold value of the number of rotations when the environmental temperature is lower than a first temperature; setting a second threshold value higher than the first threshold value as the threshold value when the environmental temperature is equal to or higher than the first temperature; determining that the flow path is normal when the number of rotations is less than the threshold value; and determining that the flow path is abnormal when the number of rotations is equal to or more than the threshold value.

The present application is based on, and claims priority from JP Application Serial Number 2023-010790, filed Jan. 27, 2023, the disclosure of which is hereby incorporated by reference herein in its entirety.

### BACKGROUND

### 1. Technical Field

The present disclosure relates to a flow path diagnosis method, a projector, and a cooling device.

### 2. Related Art

In the related art, a projector that forms an image according to image information and projects the formed image is known (for example, see JP-A-2015-108697).

The projector disclosed in JP-A-2015-108697 includes a liquid crystal panel that modulates an incident light and a cooling device that cools the liquid crystal panel. The cooling device includes an optical element holder, a liquid pressure feeder, a supply tank, a heat exchange unit, a plurality of tubular members, and a cooling fan. Among these parts, the optical element holder has a flow path through which a cooling liquid flows, and holds the liquid crystal panel. The heat exchange unit is coupled to the optical element holder via the plurality of tubular members. The cooling liquid flows from the optical element holder to the heat exchange unit. The heat exchange unit includes a heat receiver, a Peltier element as a thermoelectric conversion element, a heat sink, and the like. The heat receiver receives heat of the liquid crystal panel via the optical element holder and the cooling liquid. The Peltier element conducts the heat received by the heat receiver to the heat sink. The cooling fan blows cooling air to the heat sink to dissipate the heat from the heat sink.

JP-A-2015-108697 is an example of the related art.

The cooling device disclosed in JP-A-2015-108697 does not have a function of diagnosing a state of the flow path for the cooling liquid. Therefore, for example, when the flow path falls into a closed state, the projector may be used in a state where the liquid crystal panel as a cooling target is not cooled.

### SUMMARY

A flow path diagnosis method according to an aspect of the present disclosure includes: acquiring the number of rotations of a pump configured to send a refrigerant for cooling a cooling target to a flow path through which the refrigerant circulates; acquiring an environmental temperature; setting a first threshold value as a threshold value of the number of rotations when the environmental temperature is lower than a first temperature; setting a second threshold value higher than the first threshold value as the threshold value when the environmental temperature is equal to or higher than the first temperature; determining that the flow path is normal when the number of rotations is less than the threshold value; and determining that the flow path is abnormal when the number of rotations is equal to or more than the threshold value.

A projector according to an aspect of the present disclosure includes: an optical device; a cooler disposed in the optical device; a flow path coupled to the cooler; a pump configured to send a refrigerant to the flow path; a sensor configured to detect an environmental temperature; and a control circuit configured to acquire the number of rotations of the pump, acquire the environmental temperature based on an output signal of the sensor, set a first threshold value as a threshold value of the number of rotations when the environmental temperature is lower than a first temperature, set a second threshold value higher than the first threshold value as the threshold value when the environmental temperature is equal to or higher than the first temperature, determine that the flow path is normal when the number of rotations is less than the threshold value, and determine that the flow path is abnormal when the number of rotations is equal to or more than the threshold value.

A cooling device according to an aspect of the present disclosure includes: a cooler; a flow path coupled to the cooler; a pump configured to send a refrigerant to the flow path; a sensor configured to detect an environmental temperature; and a control circuit configured to acquire the number of rotations of the pump, acquire the environmental temperature based on an output signal of the sensor, set a first threshold value as a threshold value of the number of rotations when the environmental temperature is lower than a first temperature, set a second threshold value higher than the first threshold value as the threshold value when the environmental temperature is equal to or higher than the first temperature, determine that the flow path is normal when the number of rotations is less than the threshold value, and determine that the flow path is abnormal when the number of rotations is equal to or more than the threshold value.

### BRIEF DESCRIPTION OF THE DRAWINGS

FIG. 1 is a schematic diagram showing a configuration of a projector according to an embodiment.

FIG. 2 is a schematic diagram showing a configuration of a cooling device according to the embodiment.

FIG. 3 is a flowchart showing flow path diagnosis processing executed by a control circuit.

FIG. 4 is a diagram related to a threshold value of the number of rotations.

### DESCRIPTION OF EMBODIMENTS

Hereinafter, an embodiment of the present disclosure will be described with reference to the drawings. Here, in the following drawings, a scale of each member may be different from an actual scale in order to make each member a recognizable size.

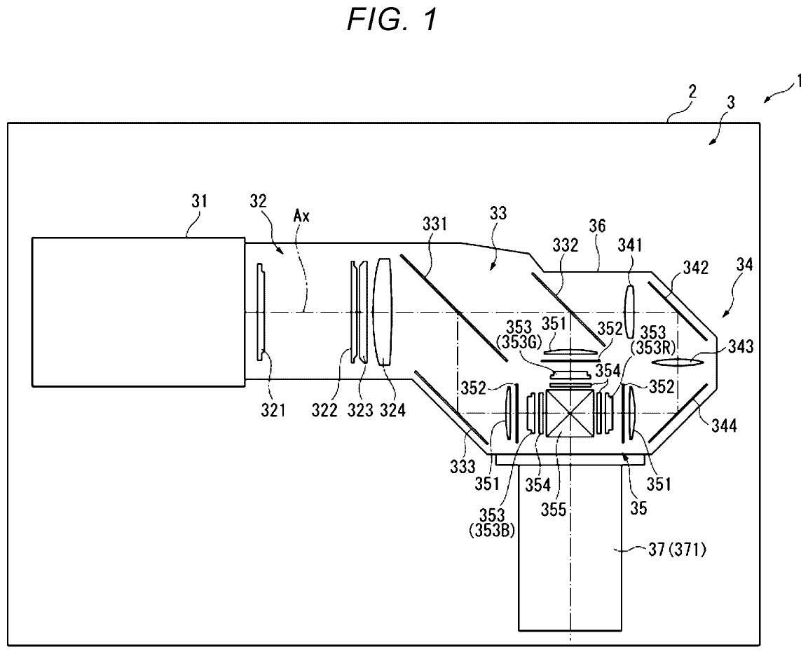

FIG. 1 is a schematic diagram showing a configuration of a projector 1 according to the embodiment.

The projector 1 according to the embodiment modulates alight emitted from alight source device 31 provided inside to form an image light according to image information, and enlarges and projects the formed image light onto a projection surface such as a screen.

As shown in FIG. 1, the projector 1 includes an outer housing 2 and an image projection device 3 accommodated in the outer housing 2. In addition, although not shown in FIG. 1, the projector 1 includes a control device that controls an operation of the projector 1, a power supply device that supplies electric power to electronic components constituting the projector 1, and a cooling device 100 that cools a cooling target constituting the projector 1. Details of the cooling device 100 will be described later.

The image projection device 3 forms an image light according to image information input from the control device and projects the formed image light. The image projection device 3 includes the light source device 31, a uniformization optical system 32, a color separation optical system 33, a relay optical system 34, an image forming device 35, an optical component housing 36, and a projection optical device 37.

The light source device 31 emits an illumination light to the uniformization optical system 32. As a configuration of the light source device 31, for example, a configuration including a solid-state light source that emits a blue light as an excitation light and a wavelength conversion element that converts at least a part of the blue light emitted from the solid-state light source into fluorescence including a green light and a red light can be illustrated. As another configuration of the light source device 31, a configuration including a light source lamp such as an ultra-high pressure mercury lamp or a configuration including a light emitting element that individually emits a blue light, a green light, and a red light can be illustrated.

The uniformization optical system 32 makes lights emitted from the light source device 31 uniform. The light made uniform passes through the color separation optical system 33 and the relay optical system 34 and illuminates a modulation region of a transmissive liquid crystal panel 353 to be described later. The uniformization optical system 32 includes two lens arrays 321 and 322, a polarization conversion element 323, and a superimposing lens 324.

The color separation optical system 33 separates a light incident from the uniformization optical system 32 into a colored light of a red light, a green light, and a blue light. The color separation optical system 33 includes dichroic mirrors 331 and 332, and a reflection mirror 333 that reflects a blue light separated by the dichroic mirror 331.

The relay optical system 34 is provided in an optical path for the red light, which is longer than optical paths for other colored lights, and reduces a loss of the red light. The relay optical system 34 includes an incident-side lens 341, a relay lens 343, and reflection mirrors 342 and 344. In the embodiment, a red light is guided to the relay optical system 34. However, the present disclosure is not limited thereto, and for example, a configuration may be adopted in which a blue light is used as a colored light having an optical path longer than other colored lights and the blue light is guided to the relay optical system 34.

The image forming device 35 modulates incident colored lights of the red light, the green light, and the blue light, synthesizes the modulated colored lights, and forms an image light. The image forming device 35 includes, according to an incident colored light, three field lenses 351, three incident-side polarization plates 352, three transmissive liquid crystal panels 353, three emission-side polarization plates 354, and one color synthesis optical system 355. In the following description, the transmissive liquid crystal panel 353 may be abbreviated as the liquid crystal panel 353.

The liquid crystal panel 353 modulates a light emitted from the light source device 31 based on an image signal input from the control device. The liquid crystal panel 353 is an example of an optical device. Specifically, the liquid crystal panel 353 modulates a colored light incident from the incident-side polarization plate 352 according to the image signal input from the control device, and emits the modulated colored light. The three liquid crystal panels 353 include a liquid crystal panel 353R for a red light, a liquid crystal panel 353G for a green light, and a liquid crystal panel 353B for a blue light.

The color synthesis optical system 355 synthesizes the three colored lights modulated by the liquid crystal panels 353B, 353G, and 353R to form an image light. The image light formed by the color synthesis optical system 355 enters the projection optical device 37. In the embodiment, the color synthesis optical system 355 is implemented by a cross dichroic prism having a substantially rectangular parallelepiped shape, but may be implemented by a plurality of dichroic mirrors.

The optical component housing 36 accommodates the uniformization optical system 32, the color separation optical system 33, the relay optical system 34, and the image forming device 35 therein. A designed optical axis Ax is set in the image projection device 3. The optical component housing 36 holds the uniformization optical system 32, the color separation optical system 33, the relay optical system 34, and the image forming device 35 at predetermined positions at the optical axis Ax. The light source device 31 and the projection optical device 37 are disposed at predetermined positions at the optical axis Ax.

The projection optical device 37 projects the image light incident from the image forming device 35 onto a projection surface such as a screen. The projection optical device 37 may be, for example, a lens assembly including a plurality of lenses (not shown) and a lens barrel 371 that accommodates the plurality of lenses.

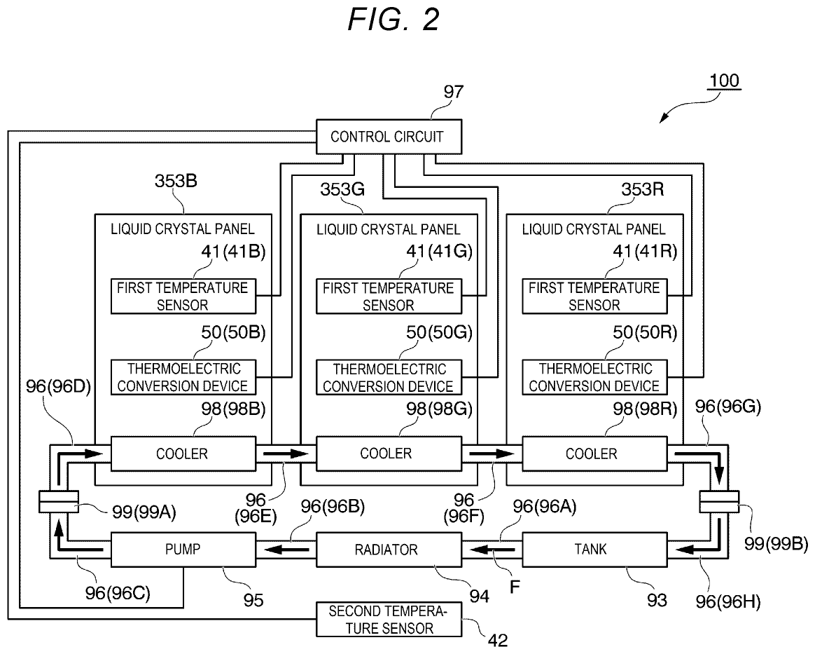

The projector 1 implemented as described above further includes the cooling device 100 that cools the three liquid crystal panels 353B, 353G, and 353R. The liquid crystal panels 353B, 353G, and 353R are examples of the cooling target. Hereinafter, a configuration of the cooling device 100 will be described with reference to FIG. 2.

FIG. 2 is a schematic diagram showing a configuration of the cooling device 100 according to the embodiment.

As shown in FIG. 2, the cooling device 100 includes three first temperature sensors 41, a second temperature sensor 42, three thermoelectric conversion devices 50, a tank 93, a radiator 94, a pump 95, eight flow paths 96, a control circuit 97, three coolers 98, and two couplers 99.

Each of the three first temperature sensors 41 is electrically coupled to the control circuit 97. The three first temperature sensors 41 include a first temperature sensor 41B disposed in the liquid crystal panel 353B, a first temperature sensor 41G disposed in the liquid crystal panel 353G, and a first temperature sensor 41R disposed in the liquid crystal panel 353R. As an example, each of the three first temperature sensors 41 is a thermistor.

The first temperature sensor 41B detects a temperature of the liquid crystal panel 353B. The first temperature sensor 41B outputs an electrical signal indicating the temperature of the liquid crystal panel 353B to the control circuit 97.

The first temperature sensor 41G detects a temperature of the liquid crystal panel 353G. The first temperature sensor 41G outputs an electrical signal indicating the temperature of the liquid crystal panel 353G to the control circuit 97.

The first temperature sensor 41R detects a temperature of the liquid crystal panel 353R. The first temperature sensor 41R outputs an electrical signal indicating the temperature of the liquid crystal panel 353R to the control circuit 97.

Each of the three thermoelectric conversion devices 50 is electrically coupled to the control circuit 97. The three thermoelectric conversion devices 50 include a thermoelectric conversion device 50B disposed in the liquid crystal panel 353B, a thermoelectric conversion device 50G disposed in the liquid crystal panel 353G, and a thermoelectric conversion device 50R disposed in the liquid crystal panel 353R. As an example, each of the three thermoelectric conversion devices 50 is a Peltier element.

The thermoelectric conversion device 50B absorbs heat of the liquid crystal panel 353B according to electric power supplied from the control circuit 97. The thermoelectric conversion device 50B releases the heat absorbed from the liquid crystal panel 353B to a cooler 98B to be described later.

The thermoelectric conversion device 50G absorbs heat of the liquid crystal panel 353G according to electric power supplied from the control circuit 97. The thermoelectric conversion device 50G releases the heat absorbed from the liquid crystal panel 353G to a cooler 98G to be described later.

The thermoelectric conversion device 50R absorbs heat of the liquid crystal panel 353R according to electric power supplied from the control circuit 97. The thermoelectric conversion device 50R releases the heat absorbed from the liquid crystal panel 353R to a cooler 98R to be described later.

The eight flow paths 96 are flow paths through which a refrigerant F for cooling the cooling target circulates. As an example, each of the eight flow paths 96 is a tubular member such as a heat pipe. The eight flow paths 96 include a first flow path 96A, a second flow path 96B, a third flow path 96C, a fourth flow path 96D, a fifth flow path 96E, a sixth flow path 96F, a seventh flow path 96G, and an eighth flow path 96H.

The three coolers 98 include the cooler 98B disposed in the liquid crystal panel 353B, the cooler 98G disposed in the liquid crystal panel 353G, and the cooler 98R disposed in the liquid crystal panel 353R. As an example, each of the three coolers 98 is a cold plate through which the refrigerant F flows.

The tank 93 stores the refrigerant F. The radiator 94 is coupled to the tank 93 via the first flow path 96A. The radiator 94 cools the refrigerant F flowing in from the tank 93 via the first flow path 96A.

The pump 95 is electrically coupled to the control circuit 97. The pump 95 is coupled to the radiator 94 via the second flow path 96B. The pump 95 is coupled to the cooler 98B via the third flow path 96C and the fourth flow path 96D. The third flow path 96C is coupled to the fourth flow path 96D via a first coupler 99A of the two couplers 99.

The pump 95 rotates in response to a control signal output from the control circuit 97 to the pump 95, thereby sending the refrigerant F flowing in from the radiator 94 to the third flow path 96C and the fourth flow path 96D coupled to the cooler 98B. The pump 95 outputs an electrical signal indicating the number of rotations of the pump 95 to the control circuit 97. Hereinafter, the electrical signal indicating the number of rotations of the pump 95 may be referred to as a rotation number signal in some cases.

The refrigerant F sent out from the pump 95 flows inside the cooler 98B. Heat released from the thermoelectric conversion device 50B to the cooler 98B is transferred to the refrigerant F flowing inside the cooler 98B. As a result, the liquid crystal panel 353B is cooled.

The cooler 98B is coupled to the cooler 98G via the fifth flow path 96E. The refrigerant F flowing from the cooler 98B via the fifth flow path 96E into the cooler 98G flows inside the cooler 98G. Heat released from the thermoelectric conversion device 50G to the cooler 98G is transferred to the refrigerant F flowing inside the cooler 98G. As a result, the liquid crystal panel 353G is cooled.

The cooler 98G is coupled to the cooler 98R via the sixth flow path 96F. The refrigerant F flowing from the cooler 98G via the sixth flow path 96F into the cooler 98R flows inside the cooler 98R. Heat released from the thermoelectric conversion device 50R to the cooler 98R is transferred to the refrigerant F flowing inside the cooler 98R. As a result, the liquid crystal panel 353R is cooled.

The cooler 98R is coupled to the tank 93 via the seventh flow path 96G and the eighth flow path 96H. The seventh flow path 96G is coupled to the eighth flow path 96H via a second coupler 99B of the two couplers 99. Thus, the refrigerant F stored in the tank 93 circulates in an order of the radiator 94, the pump 95, the cooler 98B, the cooler 98G, and the cooler 98R via the flow paths 96, and returns to the tank 93. The order in which the refrigerant F circulates through the coolers 98 is an example, and the refrigerant F may circulate through the coolers 98 in a different order.

The second temperature sensor 42 is electrically coupled to the control circuit 97. The second temperature sensor 42 is a sensor for detecting an environmental temperature. For example, the second temperature sensor 42 detects an outside temperature of the projector 1 as the environmental temperature. When the second temperature sensor 42 detects the outside temperature, the second temperature sensor 42 may be disposed in the vicinity of an intake port of the projector 1 or in the vicinity of a cooling fan of the projector 1. The second temperature sensor 42 outputs an electrical signal indicating the environmental temperature to the control circuit 97. In the following description, an output signal of the second temperature sensor 42 may be referred to as an environmental temperature signal in some cases. As an example, the second temperature sensor 42 is a thermistor.

The control circuit 97 cools, based on output signals of the three first temperature sensors 41, the three liquid crystal panels 353B, 353G, and 353R by controlling the three thermoelectric conversion devices 50 and the pump 95.

For example, the control circuit 97 is a processor that controls the three thermoelectric conversion devices 50 and the pump 95 according to a program stored in advance in a memory (not shown). For example, the processor is implemented by a single or a plurality of central processing units (CPUs). Some or all functions of the processor may be implemented by a circuit such as a digital signal processor (DSP), an application specific integrated circuit (ASIC), a programmable logic device (PLD), or a field programmable gate array (FPGA). The processor executes various types of processing in parallel or sequentially.

The control circuit 97 is not limited to a processor, and may be implemented by an analog circuit or a digital circuit. Alternatively, the control circuit 97 may be implemented by a circuit in which an analog circuit and a digital circuit are combined.

For example, the control circuit 97 executes, cooling processing when it is determined that at least one temperature of the liquid crystal panels 353B, 353G, and 353R exceeds an upper limit value of a predetermined suitable temperature range based on output signals of the three first temperature sensors 41. The cooling processing includes at least one of an increase in a flow rate of the refrigerant F due to an increase in an output of the pump 95 and an increase in an amount of heat absorbed by the thermoelectric conversion device 50 due to an increase in an output of the thermoelectric conversion device 50.

For example, when at least one of the two couplers 99 is in an unmounted state, the flow path 96 through which the refrigerant F circulates falls into a closed state. In this case, since the refrigerant F does not flow through the three coolers 98, it is difficult to sufficiently cool the liquid crystal panels 353B, 353G, and 353R as the cooling targets. The expression “the coupler 99 is in an unmounted state” means that a plug is not fitted into a socket of the coupler 99, which includes the plug and the socket.

Therefore, in the embodiment, in order to avoid a state in which the cooling target is not cooled due to the flow path 96 of the refrigerant F falling into the closed state, the control circuit 97 executes, based on an environmental temperature signal output from the second temperature sensor 42 and a rotation number signal output from the pump 95, flow path diagnosis processing of diagnosing a state of the flow path 96 through which the refrigerant F circulates.

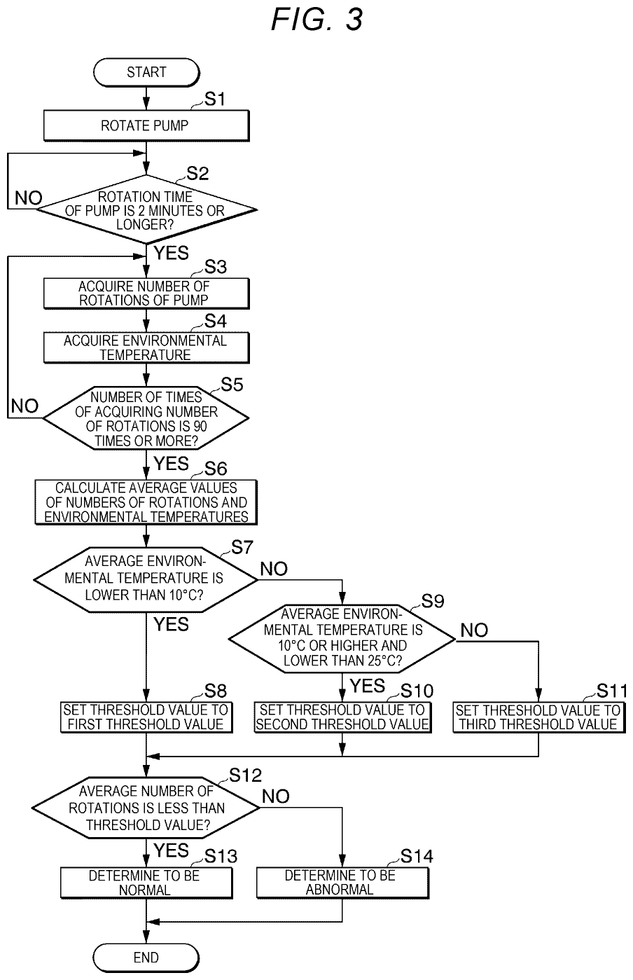

Hereinafter, the flow path diagnosis processing executed by the control circuit 97 will be described in detail with reference to FIG. 3. FIG. 3 is a flowchart showing the flow path diagnosis processing executed by the control circuit 97. When the control circuit 97 executes the flow path diagnosis processing shown in FIG. 3, a flow path diagnosis method according to the embodiment is implemented.

For example, the control circuit 97 executes the flow path diagnosis processing when a diagnosis start command is received from an external device such as a personal computer coupled to the projector 1. The control circuit 97 may execute, by operating an operation key provided in a main body of the projector 1 or a remote controller of the projector 1, the flow path diagnosis processing when it is detected that an instruction to start the diagnosis is received.

When the flow path diagnosis processing is started, the control circuit 97 first outputs a control signal to the pump 95 to rotate the pump 95 (step S1). The control circuit 97 measures a time elapsed from start of rotation of the pump 95 as a rotation time of the pump 95.

Then, the control circuit 97 determines whether the rotation time of the pump 95 is equal to or longer than a predetermined time (step S2). As an example, the predetermined time is 2 minutes. That is, in step S2, the control circuit 97 determines whether the rotation time of the pump 95 is 2 minutes or longer.

When the rotation time of the pump 95 is shorter than 2 minutes (step S2: NO), the control circuit 97 repeats processing in step S2 at regular time intervals. On the other hand, when the rotation time of the pump 95 is 2 minutes or longer (step S2: YES), the control circuit 97 proceeds to step S3 to be described later. Thus, the control circuit 97 waits until a predetermined time elapses since the pump 95 starts to rotate. This is because it takes time from the start of rotation to a steady rotation state of the pump 95.

When 2 minutes elapses since the pump 95 starts to rotate, the control circuit 97 acquires the number of rotations of the pump 95 based on a rotation number signal output from the pump 95 (step S3). The execution of the processing in step S3 by the control circuit 97 is an example of acquiring the number of rotations of the pump 95 that sends the refrigerant F for cooling the cooling target to the flow path 96 through which the refrigerant F circulates.

Then, the control circuit 97 acquires an environmental temperature based on an environmental temperature signal output from the second temperature sensor 42 (step S4). The execution of the processing in step S4 by the control circuit 97 is an example of acquiring the environmental temperature.

Then, the control circuit 97 determines whether the number of times of acquiring the number of rotations is equal to or more than a predetermined number of times (step S5). For example, the predetermined number of times is 90 times. That is, in step S5, the control circuit 97 determines whether the number of times of acquiring the number of rotations is 90 times or more.

When the number of times of acquiring the number of rotations is less than 90 times (step S5: NO), the control circuit 97 returns to the processing in step S3. On the other hand, when the number of times of acquiring the number of rotations is 90 times or more (step S5: YES), the control circuit 97 calculates respective average values of the numbers of rotations and the environmental temperatures (step S6).

As described above, the control circuit 97 repeats the processing in steps S3 and S4 at regular time intervals until the number of times of acquiring the number of rotations becomes equal to or more than the predetermined number of times. For example, the control circuit 97 repeats the processing in steps S3 and S4 at intervals of 2 seconds until the number of times of acquiring the number of rotations reaches equal to more than a predetermined number of times. The repetition of the processing in steps S3 and S4 by the control circuit 97 thus is an example of repeating acquisition of the number of rotations and acquisition of the environmental temperature until the number of times of acquiring the number of rotations becomes equal to or more than the predetermined number of times.

The execution of the processing in step S6 by the control circuit 97 is an example of calculating average values of the numbers of rotations and the environmental temperatures when the number of times of acquiring the number of rotations is equal to or more than the predetermined number of times. In the following description, the average value of the numbers of rotations may be referred to as an average number of rotations, and the respective average value of the environmental temperatures may be referred to as an average environmental temperature in some cases.

After acquiring the average number of rotations and the average environmental temperature as described above, the control circuit 97 determines whether the average environmental temperature is lower than a first temperature (step S7). As an example, the first temperature is 10° C. That is, in step S7, the control circuit 97 determines whether the average environmental temperature is lower than 10° C.

When the average environmental temperature is lower than 10° C. (step S7: YES), the control circuit 97 sets a first threshold value as a threshold value of the number of rotations (step S8). The execution of the processing in step S8 by the control circuit 97 is an example of setting the first threshold value as the threshold value of the number of rotations when the environmental temperature is lower than the first temperature. After executing the processing in step S8, the control circuit 97 proceeds to step S12 to be described later.

On the other hand, when the average environmental temperature is 10° C. or higher (step S7: NO), the control circuit 97 determines whether the average environmental temperature is equal to or higher than the first temperature and lower than a second temperature (step S9). The second temperature is higher than the first temperature. For example, the second temperature is 25° C. That is, in step S9, the control circuit 97 determines whether the average environmental temperature is 10° C. or higher and lower than 25° C.

When the average environmental temperature is 10° C. or higher and lower than 25° C. (step S9: YES), the control circuit 97 sets a second threshold value higher than the first threshold value as the threshold value of the number of rotations (step S10). The execution of the processing in step S10 by the control circuit 97 is an example of setting the second threshold value higher than the first threshold value as the threshold value when the environmental temperature is equal to or higher than the first temperature. Here, setting the second threshold value means setting the second threshold value as the threshold value when the environmental temperature is equal to or higher than the first temperature and lower than the second temperature. After executing the processing in step S10, the control circuit 97 proceeds to step S12 to be described later.

On the other hand, when the average environmental temperature is 25° C. or higher (step S9: NO), the control circuit 97 sets a third threshold value higher than the second threshold value as the threshold value of the number of rotations (step S11). The execution of the processing in step S11 by the control circuit 97 is an example of setting the third threshold value higher than the second threshold value as the threshold value when the environmental temperature is equal to or higher than the second temperature that is higher than the first temperature. After executing the processing in step S11, the control circuit 97 proceeds to step S12 to be described later.

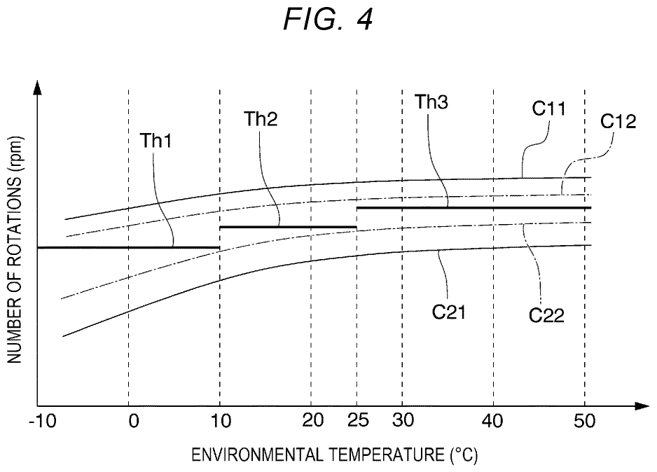

FIG. 4 is a diagram related to a threshold value of the number of rotations.

In FIG. 4, a horizontal axis represents the environmental temperature, and a vertical axis represents the number of rotations of the pump 95. In FIG. 4, Th1 indicates the first threshold value, Th2 indicates the second threshold value, and Th3 indicates the third threshold value. In FIG. 4, a curve C11 is a curve obtained by measuring a correspondence relationship between the environmental temperature and the number of rotations when at least one of the two couplers 99 is in an unmounted state, that is, when the flow path 96 for the refrigerant F falls into a closed state. A curve C21 is a curve obtained by measuring the correspondence relationship between the environmental temperature and the number of rotations when both of the two couplers 99 are in a mounted state, that is, when the flow path 96 does not fall into the closed state.

The curve C11 and the curve C21 are separated in a direction of the vertical axis. Therefore, if the threshold value of the number of rotations is set to a value in a region between the curve C11 and the curve C21, it is possible to determine whether the flow path 96 falls into the closed state by comparing an actual measurement value of the number of rotations with the threshold value. For example, when the actual measurement value of the number of rotations is less than the threshold value, it can be determined that the flow path 96 does not fall into the closed state, that is, the flow path 96 is normal, and when the actual measurement value of the number of rotations is equal to or more than the threshold value, it can be determined that the flow path 96 falls into the closed state, that is, the flow path 96 is abnormal.

However, as shown in FIG. 4, in the curve C11 and the curve C21, the number of rotations decreases as the environmental temperature decreases. Therefore, when the actual measurement value of the number of rotations is compared with only one threshold value, there is a possibility that a state of the flow path 96 cannot be accurately determined depending on the environmental temperature. Therefore, in the embodiment, three threshold values, that is, the first threshold value Th1, the second threshold value Th2, and the third threshold value Th3 are prepared in advance as the threshold value of the number of rotations. The threshold value of the number of rotations is set to any one of the first threshold value Th1, the second threshold value Th2, and the third threshold value Th3 according to an actual measurement value of the environmental temperature.

Further, in the embodiment, the first threshold value Th1, the second threshold value Th2, and the third threshold value Th3 are set to values that are not affected by individual variations in the projector 1. In FIG. 4, a curve C12 is a curve having the lowest number of rotations among a plurality of curves obtained by measuring the correspondence relationship between the environmental temperature and the number of rotations for the plurality of projectors 1 in which the flow path 96 falls into the closed state, or a curve indicating values calculated based on the plurality of curves. In FIG. 4, a curve C22 is a curve having the highest number of rotations among a plurality of curves obtained by measuring the correspondence relationship between the environmental temperature and the number of rotations for the plurality of projectors 1 in which the flow path 96 does not fall into the closed state, or a curve indicating values calculated based on the plurality of curves. In order not to be affected by the individual variations in the projector 1, the first threshold value Th1, the second threshold value Th2, and the third threshold value Th3 are set to values in a region between the curve C12 and the curve C22.

The first threshold value Th1 is set to a value in a region between the curve C12 and the curve C22 where the environmental temperature is lower than 10° C. The second threshold value Th2 is set to a value in a region between the curve C12 and the curve C22 where the environmental temperature is 10° C. or higher and lower than 25° C. The second threshold value Th2 is set to a value higher than the first threshold value Th1. The third threshold value Th3 is set to a value in a region between the curve C12 and the curve C22 where the environmental temperature is 25° C. or higher. The third threshold value Th3 is set to a value higher than the second threshold value Th2.

In the embodiment, the first threshold value Th1, the second threshold value Th2, and the third threshold value Th3 as described above are prepared in advance, and the control circuit 97 sets the threshold value of the number of rotations to any one of the first threshold value Th1, the second threshold value Th2, and the third threshold value Th3 according to the actual measurement value of the environmental temperature. That is, as described above, when the average environmental temperature is lower than 10° C., the control circuit 97 sets the first threshold value Th1 as the threshold value of the number of rotations. When the average environmental temperature is 10° C. or higher and lower than 25° C., the control circuit 97 sets the second threshold value Th2 as the threshold value of the number of rotations. When the average environmental temperature is 25° C. or higher, the control circuit 97 sets the third threshold value Th3 as the threshold value of the number of rotations.

The description is continued by referring back to FIG. 3 below.

After executing any one of the processing in steps S8, S10, and S11, the control circuit 97 determines whether the average number of rotations is less than the threshold value (step S12). When the average number of rotations is less than the threshold value (step S12: YES), the control circuit 97 determines that the flow path 96 is normal (step S13). The execution of the processing in step S13 by the control circuit 97 is an example of determining that the flow path 96 is normal when the number of rotations is less than the threshold value.

On the other hand, when the average number of rotations is equal to or more than the threshold value (step S12: NO), the control circuit 97 determines that the flow path 96 is abnormal (step S14). The execution of the processing in step S14 by the control circuit 97 is an example of determining that the flow path 96 is abnormal when the number of rotations is equal to or more than the threshold value.

When the average environmental temperature is lower than 10° C., the first threshold value Th1 is set as the threshold value of the number of rotations. As can be understood from FIG. 4, when the average number of rotations is less than the first threshold value Th1, it is estimated that the flow path 96 does not fall into the closed state, and thus it can be determined that the flow path 96 is normal. On the other hand, when the average number of rotations is equal to or more than the first threshold value Th1, it is estimated that the flow path 96 falls into the closed state, and thus it can be determined that the flow path 96 is abnormal.

When the average environmental temperature is 10° C. or higher and lower than 25° C., the second threshold value Th2 is set as the threshold value of the number of rotations. As can be understood from FIG. 4, when the average number of rotations is less than the second threshold value Th2, it is estimated that the flow path 96 does not fall into the closed state, and thus it can be determined that the flow path 96 is normal. On the other hand, when the average number of rotations is equal to or more than the second threshold value Th2, it is estimated that the flow path 96 falls into the closed state, and thus it can be determined that the flow path 96 is abnormal.

When the average environmental temperature is 25° C. or higher, the third threshold value Th3 is set as the threshold value of the number of rotations. As can be understood from FIG. 4, when the average number of rotations is less than the third threshold value Th3, it is estimated that the flow path 96 does not fall into the closed state, and thus it can be determined that the flow path 96 is normal. On the other hand, when the average number of rotations is equal to or more than the third threshold value Th3, it is estimated that the flow path 96 falls into the closed state, and thus it can be determined that the flow path 96 is abnormal.

The above is the description related to the flow path diagnosis processing.

In the flow path diagnosis processing, the control circuit 97 may output a notification of a determination result of the flow path 96 using at least one of a light, sound, and an image. For example, when a light is used, the control circuit 97 causes an LED lamp in the projector 1 to emit a light in a color corresponding to the determination result of the flow path 96. For example, when sound is used, the control circuit 97 controls a speaker in the projector 1 to output sound corresponding to the determination result of the flow path 96 from the speaker. For example, when an image is used, the control circuit 97 controls the liquid crystal panel 353 to project an image indicating the determination result of the flow path 96 onto a projection surface such as a screen.

In the flow path diagnosis processing, the control circuit 97 may generate control information including the determination result of the flow path 96 and transmit the generated control information to the control device. The control device may output a notification of the determination result in the received control information using at least one of a light, sound, and an image.

### Effects of Embodiment

As described above, the flow path diagnosis method according to the embodiment includes: acquiring the number of rotations of the pump 95 configured to send the refrigerant F for cooling the cooling target to the flow path 96 through which the refrigerant F circulates; acquiring the environmental temperature; setting the first threshold value as the threshold value of the number of rotations when the environmental temperature is lower than the first temperature; setting the second threshold value higher than the first threshold value as the threshold value when the environmental temperature is equal to or higher than the first temperature; determining that the flow path 96 is normal when the number of rotations is less than the threshold value; and determining that the flow path 96 is abnormal when the number of rotations is equal to or more than the threshold value.

According to the flow path diagnosis method in the embodiment, for example, when the flow path 96 for the refrigerant F falls into a closed state due to at least one of the two couplers 99 being in the unmounted state, it can be determined that the flow path 96 is abnormal. Therefore, according to the flow path diagnosis method in the embodiment, it is possible to avoid a state in which the cooling target is not cooled due to the flow path 96 for the refrigerant F falling into a closed state.

The flow path diagnosis method according to the embodiment further includes: setting a third threshold value higher than the second threshold value as the threshold value when the environmental temperature is equal to or higher than the second temperature that is higher than the first temperature, in which setting the second threshold value is to set the second threshold value as the threshold value when the environmental temperature is equal to or higher than the first temperature and lower than the second temperature.

According to the flow path diagnosis method in the embodiment, since the threshold value of the number of rotations is set to one value selected from three threshold value candidates including the first threshold value, the second threshold value, and the third threshold value according to the acquired environmental temperature, accuracy of determining a state of the flow path 96 can be improved.

The flow path diagnosis method according to the embodiment further includes: repeatedly acquiring the number of rotations and acquiring the environmental temperature until the number of times of acquiring the number of rotations becomes equal to or more than a predetermined number of times; and calculating respective average values of the numbers of rotations and the environmental temperatures when the number of times of acquiring the number of rotations is equal to or more than the predetermined number of times.

According to the flow path diagnosis method in the embodiment, since variations in the acquired number of rotations and the environmental temperature are reduced by calculating the respective average values of the numbers of rotations and the environmental temperatures acquired a plurality of numbers of times, the accuracy of determining the state of the flow path 96 can be further improved.

The flow path diagnosis method according to the embodiment further includes: outputting a notification of a determination result of the flow path 96 using at least one of a light, sound, and an image.

According to the flow path diagnosis method in the embodiment, a user can know the determination result of the flow path 96, that is, a diagnosis result of the flow path 96 by outputting a notification of the determination result of the flow path 96 using at least one of a light, sound, and an image.

The flow path diagnosis method according to the embodiment further includes: generating control information including a determination result of the flow path 96.

According to the flow path diagnosis method in the embodiment, it is possible to provide the control information to various devices such as the control device by generating the control information including the determination result of the flow path 96.

In the flow path diagnosis method according to the embodiment, the cooling target is an optical device.

According to the flow path diagnosis method in the embodiment, since the cooling target is the optical device, it is possible to prevent the optical device from falling into an uncooled state due to the flow path 96 falling into a closed state.

In the flow path diagnosis method according to the embodiment, the cooler is disposed in the cooling target, the flow path is coupled to the cooler, and the refrigerant is sent to the cooler via the flow path.

According to the flow path diagnosis method in the embodiment, since the cooler is disposed in the cooling target, the flow path is coupled to the cooler, and the refrigerant is sent to the cooler via the flow path, the cooling target can be effectively cooled.

In the flow path diagnosis method according to the embodiment, a thermoelectric conversion device is disposed in the cooling target.

According to the flow path diagnosis method in the embodiment, since the thermoelectric conversion device is disposed in the cooling target, the cooling target can be more effectively cooled. In general, in a liquid cooling method, rapid temperature adjustment is difficult due to a high specific heat of a liquid refrigerant, but by using a thermoelectric conversion device such as a Peltier element, rapid cooling can be achieved, thereby reducing electric power consumption.

The projector 1 according to the embodiment includes: the liquid crystal panel 353 that is an example of the optical device; the cooler 98 disposed in the liquid crystal panel 353; the flow path 96 coupled to the cooler 98; the pump 95 configured to send the refrigerant F to the flow path 96; the second temperature sensor 42 that is an example of a sensor configured to detect the environmental temperature; and the control circuit 97 configured to acquire the number of rotations of the pump 95, acquire the environmental temperature based on an output signal of the second temperature sensor 42, set the first threshold value as the threshold value of the number of rotations when the environmental temperature is lower than the first temperature, set the second threshold value higher than the first threshold value as the threshold value when the environmental temperature is equal to or higher than the first temperature, determine that the flow path 96 is normal when the number of rotations is less than the threshold value, and determine that the flow path 96 is abnormal when the number of rotations is equal to or more than the threshold value.

According to the projector 1 in the embodiment, for example, when the flow path 96 for the refrigerant F falls into a closed state due to at least one of the two couplers 99 being in the unmounted state, the control circuit 97 can determine that the flow path 96 is abnormal. Therefore, according to the projector 1 of the embodiment, it is possible to avoid a state in which the liquid crystal panel 353 is not cooled due to the flow path 96 for the refrigerant F falling into the closed state.

A cooling device 100 according to the embodiment includes: the cooler 98; the flow path 96 coupled to the cooler 98; the pump 95 configured to send the refrigerant F to the flow path 96; the second temperature sensor 42 that is an example of a sensor configured to detect an environmental temperature; and the control circuit 97 configured to acquire the number of rotations of the pump 95, acquire the environmental temperature based on an output signal of the second temperature sensor 42, set the first threshold value as the threshold value of the number of rotations when the environmental temperature is lower than the first temperature, set the second threshold value higher than the first threshold value as the threshold value when the environmental temperature is equal to or higher than the first temperature, determine that the flow path 96 is normal when the number of rotations is less than the threshold value, and determine that the flow path 96 is abnormal when the number of rotations is equal to or more than the threshold value.

According to the cooling device 100 in the embodiment, for example, when the flow path 96 for the refrigerant F falls into a closed state due to at least one of the two couplers 99 being in the unmounted state, the control circuit 97 can determine that the flow path 96 is abnormal. Therefore, according to the cooling device 100 in the embodiment, it is possible to avoid a state in which the cooling target is not cooled due to the flow path 96 for the refrigerant F falling into a closed state.

Although the embodiment of the present disclosure is described above, the technical scope of the present disclosure is not limited to the above embodiment, and various modifications can be made without departing from the gist of the present disclosure.

In the embodiment described above, although the embodiment is illustrated in which one value selected from three threshold value candidates including the first threshold value, the second threshold value, and the third threshold value is set as the threshold value of the number of rotations, the present disclosure is not limited thereto. For example, one value selected from two threshold value candidates including the first threshold value and the second threshold value may be set as the threshold value of the number of rotations. Alternatively, one value selected from four or more threshold value candidates may be set as the threshold value of the number of rotations.

In the above embodiment, although the embodiment is illustrated in which the optical device as the cooling target is the transmissive liquid crystal panel 353, the present disclosure is not limited thereto. For example, the optical device as the cooling target may be another optical device such as a reflective liquid crystal panel. In the above embodiment, although the cooling device 100 that cools the liquid crystal panel 353 of the projector 1 is illustrated, the cooling device in the present disclosure can be widely applied as a device that cools various cooling targets.

### Summary of Present Disclosure

Hereinafter, summary of the present disclosure is appended below.

### Appendix 1

A flow path diagnosis method including: acquiring the number of rotations of a pump configured to send a refrigerant for cooling a cooling target to a flow path through which the refrigerant circulates; acquiring an environmental temperature; setting a first threshold value as a threshold value of the number of rotations when the environmental temperature is lower than a first temperature; setting a second threshold value higher than the first threshold value as the threshold value when the environmental temperature is equal to or higher than the first temperature; determining that the flow path is normal when the number of rotations is less than the threshold value; and determining that the flow path is abnormal when the number of rotations is equal to or more than the threshold value.

According to the flow path diagnosis method in appendix 1, it is possible to determine that the flow path is abnormal, for example, when the flow path for the refrigerant falls into a closed state. Therefore, according to the flow path diagnosis method in appendix 1, it is possible to avoid a state in which the cooling target is not cooled due to the flow path for the refrigerant falling into a closed state.

### Appendix 2

The flow path diagnosis method according to appendix 1 further including: setting a third threshold value higher than the second threshold value as the threshold value when the environmental temperature is equal to or higher than a second temperature that is higher than the first temperature, in which setting the second threshold value is to set the second threshold value as the threshold value when the environmental temperature is equal to or higher than the first temperature and lower than the second temperature.

According to the flow path diagnosis method in appendix 2, since the threshold value of the number of rotations is set to one value selected from three threshold value candidates including the first threshold value, the second threshold value, and the third threshold value according to the acquired environmental temperature, accuracy of determining a state of the flow path can be improved.

### Appendix 3

The flow path diagnosis method according to appendix 1 or 2 further including: repeatedly acquiring the number of rotations and acquiring the environmental temperature until the number of times of acquiring the number of rotations becomes equal to or more than a predetermined number of times; and calculating respective average values of the numbers of rotations and the environmental temperatures when the number of times of acquiring the number of rotations is equal to or more than the predetermined number of times.

According to the flow path diagnosis method in appendix 3, since variations in the acquired number of rotations and the environmental temperature are reduced by calculating the respective average values of the numbers of rotations and the environmental temperatures acquired a plurality of numbers of times, the accuracy of determining the state of the flow path can be further improved.

### Appendix 4

The flow path diagnosis method according to any one of appendixes 1 to 3, further including: outputting a notification of a determination result of the flow path using at least one of a light, sound, and an image.

According to the flow path diagnosis method in appendix 4, a user can know the determination result of the flow path, that is, a diagnosis result of the flow path by outputting the notification of the determination result of the flow path using at least one of a light, sound, and an image.

### Appendix 5

The flow path diagnosis method according to any one of appendixes 1 to 4, further including: generating control information including a determination result of the flow path.

According to the flow path diagnosis method in appendix 5, it is possible to provide the control information to various devices by generating the control information including the determination result of the flow path.

### Appendix 6

The flow path diagnosis method according to any one of appendixes 1 to 5, in which the cooling target is an optical device.

According to the flow path diagnosis method in appendix 6, since the cooling target is the optical device, it is possible to prevent the optical device from falling into an uncooled state due to the flow path falling into a closed state.

### Appendix 7

The flow path diagnosis method according to any one of appendixes 1 to 6, in which a cooler is disposed in the cooling target, the flow path is coupled to the cooler, and the refrigerant is sent to the cooler via the flow path.

According to the flow path diagnosis method in appendix 7, since the cooler is disposed in the cooling target, the flow path is coupled to the cooler, and the refrigerant is sent to the cooler via the flow path, the cooling target can be effectively cooled.

### Appendix 8

The flow path diagnosis method according to any one of appendixes 1 to 7, in which a thermoelectric conversion device is disposed in the cooling target.

According to the flow path diagnosis method in appendix 8, since the thermoelectric conversion device is disposed in the cooling target, the cooling target can be more effectively cooled. In general, in a liquid cooling method, rapid temperature adjustment is difficult due to a high specific heat of a liquid refrigerant, but by using the thermoelectric conversion device such as a Peltier element, rapid cooling can be achieved, thereby reducing electric power consumption.

### Appendix 9

A projector including: an optical device; a cooler disposed in the optical device; a flow path coupled to the cooler; a pump configured to send a refrigerant to the flow path; a sensor configured to detect an environmental temperature; and a control circuit configured to acquire the number of rotations of the pump, acquire the environmental temperature based on an output signal of the sensor, set a first threshold value as a threshold value of the number of rotations when the environmental temperature is lower than a first temperature, set a second threshold value higher than the first threshold value as the threshold value when the environmental temperature is equal to or higher than the first temperature, determine that the flow path is normal when the number of rotations is less than the threshold value, and determine that the flow path is abnormal when the number of rotations is equal to or more than the threshold value.

According to the projector in appendix 9, the control circuit can determine that the flow path is abnormal, for example, when the flow path for the refrigerant falls into a closed state. Therefore, according to the projector in appendix 8, it is possible to avoid a state in which the optical device is not cooled due to the flow path for the refrigerant falling into a closed state.

### Appendix 10

A cooling device including: a cooler; a flow path coupled to the cooler; a pump configured to send a refrigerant to the flow path; a sensor configured to detect an environmental temperature; and a control circuit configured to acquire the number of rotations of the pump, acquire the environmental temperature based on an output signal of the sensor, set a first threshold value as a threshold value of the number of rotations when the environmental temperature is lower than a first temperature, set a second threshold value higher than the first threshold value as the threshold value when the environmental temperature is equal to or higher than the first temperature, determine that the flow path is normal when the number of rotations is less than the threshold value, and determine that the flow path is abnormal when the number of rotations is equal to or more than the threshold value.

According to the cooling device in appendix 10, the control circuit can determine that the flow path is abnormal, for example, when the flow path for the refrigerant falls into a closed state. Therefore, according to the cooling device in appendix 9, it is possible to avoid a state in which the cooling target is not cooled due to the flow path for the refrigerant falling into a closed state.

What is claimed is:

1. A flow path diagnosis method comprising:
acquiring the number of rotations of a pump configured to send a refrigerant for cooling a cooling target to a flow path through which the refrigerant circulates;
acquiring an environmental temperature;
setting a first threshold value as a threshold value of the number of rotations when the environmental temperature is lower than a first temperature;
setting a second threshold value higher than the first threshold value as the threshold value when the environmental temperature is equal to or higher than the first temperature;
determining that the flow path is normal when the number of rotations is less than the threshold value; and
determining that the flow path is abnormal when the number of rotations is equal to or more than the threshold value.

2. The flow path diagnosis method according to claim 1, further comprising:
setting a third threshold value higher than the second threshold value as the threshold value when the environmental temperature is equal to or higher than a second temperature that is higher than the first temperature, wherein
setting the second threshold value is to set the second threshold value as the threshold value when the environmental temperature is equal to or higher than the first temperature and lower than the second temperature.

3. The flow path diagnosis method according to claim 1, further comprising:
repeatedly acquiring the number of rotations and acquiring the environmental temperature until the number of times of acquiring the number of rotations becomes equal to or more than a predetermined number of times; and
calculating respective average values of the numbers of rotations and the environmental temperatures when the number of times of acquiring the number of rotations is equal to or more than the predetermined number of times.

4. The flow path diagnosis method according to claim 1, further comprising:
outputting a notification of a determination result of the flow path using at least one of a light, sound, and an image.

5. The flow path diagnosis method according to claim 1, further comprising:
generating control information including a determination result of the flow path.

6. The flow path diagnosis method according to claim 1, wherein
the cooling target is an optical device.

7. The flow path diagnosis method according to claim 1, wherein
a cooler is disposed in the cooling target,
the flow path is coupled to the cooler, and
the refrigerant is sent to the cooler via the flow path.

8. The flow path diagnosis method according to claim 1, wherein
a thermoelectric conversion device is disposed in the cooling target.

9. A projector comprising:
an optical device;
a cooler disposed in the optical device;
a flow path coupled to the cooler;
a pump configured to send a refrigerant to the flow path;
a sensor configured to detect an environmental temperature; and
a control circuit configured to
acquire the number of rotations of the pump,
acquire the environmental temperature based on an output signal of the sensor,
set a first threshold value as a threshold value of the number of rotations when the environmental temperature is lower than a first temperature,
set a second threshold value higher than the first threshold value as the threshold value when the environmental temperature is equal to or higher than the first temperature,
determine that the flow path is normal when the number of rotations is less than the threshold value, and
determine that the flow path is abnormal when the number of rotations is equal to or more than the threshold value.

10. A cooling device comprising:
a cooler;
a flow path coupled to the cooler;
a pump configured to send a refrigerant to the flow path;
a sensor configured to detect an environmental temperature; and
a control circuit configured to
acquire the number of rotations of the pump,
acquire the environmental temperature based on an output signal of the sensor,
set a first threshold value as a threshold value of the number of rotations when the environmental temperature is lower than a first temperature,
set a second threshold value higher than the first threshold value as the threshold value when the environmental temperature is equal to or higher than the first temperature,
determine that the flow path is normal when the number of rotations is less than the threshold value, and
determine that the flow path is abnormal when the number of rotations is equal to or more than the threshold value.
